(19) United States
(12) Patent Application Publication
(10) Pub. No.: US 2011/0109210 A1
(43) Pub. Date: May 12, 2011

(54) METHOD OF INSERTING BRITTLE MATERIAL IN PLASTIC SHELL AND ELECTRONIC DEVICE HAVING THE PLASTIC SHELL

(76) Inventors: Dingwen Mao, Shenzhen (CN); Guiying Ma, Shenzhen (CN); Mingzhu Chang, Shenzhen (CN); Jiaxin Zhang, Shenzhen (CN)

(21) Appl. No.: 13/007,928

(22) Filed: Jan. 17, 2011

Related U.S. Application Data
(63) Continuation-in-part of application No. PCT/CN2009/000592, filed on May 26, 2009.

(30) Foreign Application Priority Data
Jul. 18, 2008 (CN) 200810068557.3

(51) Int. Cl. H05K 5/02; B29C 45/14

(52) U.S. Cl. 312/223.1; 264/275

(57) ABSTRACT

A method of inserting a brittle material into a plastic shell comprises: a) processing the brittle material, so that the brittle material comprises an embedded portion to be embedded into the plastic shell, an exposed portion to be exposed outside the plastic shell, and a positioning portion between the embedded portion and the exposed portion; b) putting the exposed portion and at least part of the position portion into a fixed mold core of an injection mold, with the brittle material being positioned in the fixed mold core by the positioning portion; and c) injecting molten plastic into the mold to form the plastic shell, in which the embedded portion and at least part of the positioning portion are embedded into the plastic shell with the exposed portion and the remaining or the positioning portion being exposed outside the plastic shell. An electronic device having the above plastic shell is also provided.

### CROSS-REFERENCE TO RELATED APPLICATIONS

This application is a continuation-in-part of PCT international application No. PCT/CN2009/000592 designating the United States of America, which claims priority to and benefit of Chinese Patent Application No. 200810068557.3, filed with China's State Intellectual Property Office on Jul. 18, 2008. The disclosures of both the PCT international application and Chinese application are incorporated by reference herein in their entirety.

### BACKGROUND OF THE INVENTION

1. Field of the Invention

The present invention relates to a method of inserting a brittle material, such as a precious stone into a plastic shell via injection molding and an electronic device having the plastic shell.

2. Background of the Related Art

The current process of inserting a brittle material such as a precious stone into an electronic device includes inserting the brittle material into the metal shell of the electronic device. For example, the precious stone is fixed to the metal shell using a claw setting. More specifically, a metal claw having four or six nails is formed on the metal shell using CNC (Computer Numerical Control). Then, the precious stone is clipped onto a metal holder using the metal claw.

Although the current method can insert precious stones into a metal shell, the mobile phones currently use a plastic shell. Because some properties such as ductility, strength etc. of a plastic are inferior to those of a metal, it is impossible to form a claw for inserting the precious stone using the current process.

To insert brittle materials into the plastic shell, gluing is used to adhere the brittle materials to the plastic shell of an electronic device. The process not only causes “albinism” phenomena but also does not always adequately secure the brittle material to the plastic shell, resulting in the brittle material falling off the plastic shell. This may seriously affect the aesthetic appearance and usage of the electronic device.

### SUMMARY OF THE INVENTION

The present invention is directed to solving at least one of the problems existing in the prior art. Accordingly, the present invention provides a method for inserting a brittle material, such as precious stone, into a plastic shell, which can ensure the aesthetic appearance of the shell and prevents the inserted precious stone from falling off.

Further, the present invention provides an electronic device having the shell thereof.

According to an aspect of the invention, a method for inserting a brittle material on a plastic shell comprises: a) processing the brittle material so that the brittle material comprises an embedded portion to be embedded into the plastic shell, an exposed portion to be exposed outside the plastic shell, and a positioning portion formed between the embedded portion and the exposed portion; b) putting the exposed portion and at least part of the positioning portion into a fixed mold core of an injection mold, with the precious stone being positioned in the fixed mold core by the positioning portion; and c) injecting molten plastic into the mold to form the plastic shell, in which the embedded portion and at least part of the positioning portion are embedded into the plastic shell with the exposed portion and the remaining of the positioning portion being exposed outside the plastic shell.

According to another embodiment of the invention, an electronic device comprises a shell made of a plastic inserted with a brittle material according to the method mentioned above.

In an embodiment, the positioning portion includes a circular column or a pyramid in an embedding direction of the brittle material.

In an embodiment, the step a) further comprises: processing an end face of the exposed portion of the brittle material into a planar surface perpendicular to the embedding direction of the brittle material.

In an embodiment, the step b) further comprises: suctioning the end face of the exposed portion with a suction device provided in the fixed mold core to position the brittle material additionally during injection molding.

In an embodiment, the suction device is attached to an insert which can be provided in the fixed mold core.

In an embodiment, the step a) further comprises: processing the embedded portion of the brittle material into a conical shape; and processing the exposed portion into a truncated-cone shape.

In an embodiment, the positioning portion has a height of about 1/10-⅕ of that of the brittle material in the embedding direction.

In an embodiment, an aperture of said mold core is formed on the fixed mold core with a size that matches that of the positioning portion of the brittle material so that the brittle material can be accurately positioned in the aperture.

In an embodiment, the fixed mold core is formed with a plurality of apertures which are arranged into a predetermined pattern.

According to an aspect of the invention, a method for inserting a precious stone on a plastic shell comprises: a) processing the precious stone so that the stone comprises an embedded portion to be embedded into the plastic shell, an exposed portion to be exposed outside the plastic shell, and a positioning portion formed between the embedded portion and the exposed portion; b) putting the exposed portion and at least part of the positioning portion into a fixed mold core of an injection mold, with the precious stone being positioned in the fixed mold core by the positioning portion; and c) injecting molten plastic into the mold to form the plastic shell, in which the embedded portion and at least part of the positioning portion are embedded into the plastic shell with the exposed portion and the remaining of the positioning portion being exposed outside the plastic shell.

In an embodiment, the positioning portion includes a circular column or a pyramid in an embedding direction of the precious stone.

In an embodiment, the step a) further comprises: processing an end face of the exposed portion of the precious stone into a planar surface perpendicular to the embedding direction of the precious stone.

In an embodiment, the step b) further comprises: suctioning the end face of the exposed portion with a suction device provided in the fixed mold core to position the precious stone additionally during injection molding.

In an embodiment, the suction device is attached to an insert which can be provided in the fixed mold core.

In an embodiment, the step a) further comprises: processing the embedded portion of the precious stone into a conical shape; and processing the exposed portion into a truncated-cone shape.

In an embodiment, the positioning portion has a height of about 1/10-⅕ of that of the precious stone in the embedding direction.

In an embodiment, an aperture of said mold core is formed on the fixed mold core with a size that matches that of the positioning portion of the precious stone so that the precious stone can be accurately positioned in the aperture.

In an embodiment, the fixed mold core is formed with a plurality of apertures which are arranged into a predetermined pattern.

According to an embodiment of the invention, a mobile communication device comprises a shell made of a plastic inserted with a precious stone according to the method mentioned above.

According to an embodiment of the invention, the precious stone can be inserted into a plastic shell of an electronic device such as a mobile phone without falling off using a positioning portion formed on the precious stone during injection molding. Further, an excellent aesthetic appearance of the plastic shell can be achieved, ameliorating or overcoming shortcomings caused by adhesive such as glue. In addition, one or more precious stones can be arranged on the plastic shell to form a predetermined pattern such as a heart shape etc. to enhance the aesthetic attraction to normal users.

### BRIEF DESCRIPTION OF THE DRAWINGS

The invention will be better understood, and other objects, features, details and advantages thereof will become more clearly apparent in the explanatory description which follows, made with reference to the appended schematic drawings only given as an example illustrating an embodiment of the invention and wherein:

FIG. 1 shows a flow chart of a method for inserting a precious stone into a plastic shell according to an embodiment of the invention;

FIG. 1A shows a flow chart of a method for inserting a glass into a plastic shell according to an embodiment of the invention;

FIG. 1B shows a flow chart of a method for inserting a brittle material in a plastic shell according to an embodiment of the invention;

FIG. 2 shows a schematic view of a precious stone according to an embodiment of the invention;

FIG. 2A shows a schematic view of a glass according to an embodiment of the invention;

FIGS. 3A and 3B show plan views of the stone in FIG. 1 and FIG. 1A respectively;

FIG. 4 shows a schematic sectional view of a suction device according to an embodiment of the invention;

FIG. 5 shows a combined schematic view of the suction device according to an embodiment of the invention with the precious stone during injection molding;

FIG. 5A shows a combined schematic view of the suction device according to an embodiment of the invention with a glass during injection molding;

FIG. 6 shows a partial schematic view of a mold according to an embodiment of the invention; and

FIG. 7 shows an enlarged schematic view of part A indicated in FIG. 6.

### DETAILED DESCRIPTION OF THE PREFERRED EMBODIMENTS

The aforementioned features and advantages of the invention as well as additional features and advantages thereof will be described in detail with reference to accompanying figures. Further, like reference numerals designate like parts throughout the several views.

All numbers relating to dimensions components, numbers, properties and/or contents of features described hereinafter are assumed to be modified by the term ‘about’ unless otherwise specified or expressly termed. Further, the singular form of a word should be interpreted in the plural, and the words “and” and “or” should be construed conjunctively or disjunctively.

Hereinafter, an electronic device such as a mobile phone is used for depicting the method of inserting a brittle material, such as a precious stone, in a plastic shell. However, the mobile phone and the precious stone are illustrated for exemplary purpose only rather than limitation of scope of the invention. It is obvious for a person normally skilled in the art to apply the solution hereafter described to mobile communication device such as a pager, PDA, blackberry, or an iPhone etc. The term “brittle material” as used herein comprises materials that may break suddenly under stress at a point just beyond its elastic limit, including, for example and without limit to, stones including precious stones, glasses, ceramics, cast ions, and combinations thereof.

### EXAMPLE 1

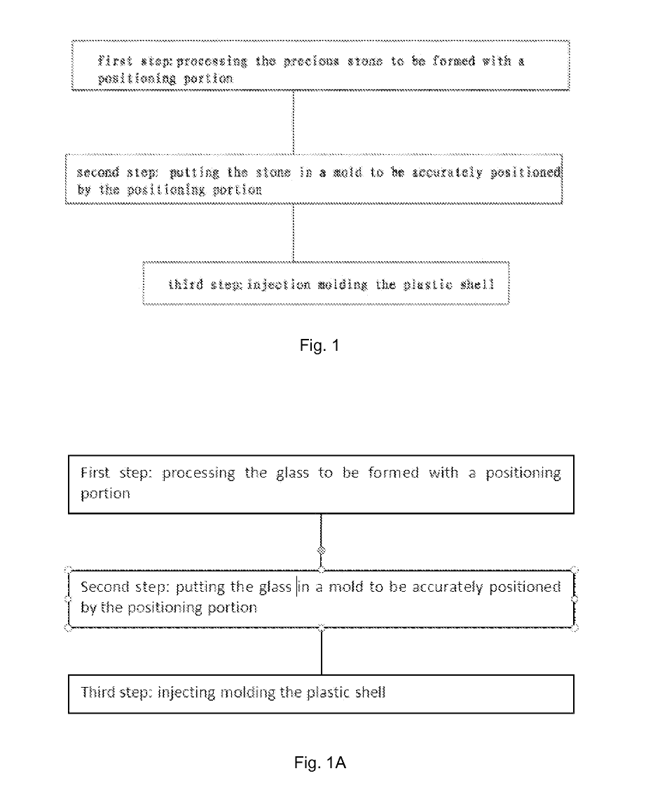

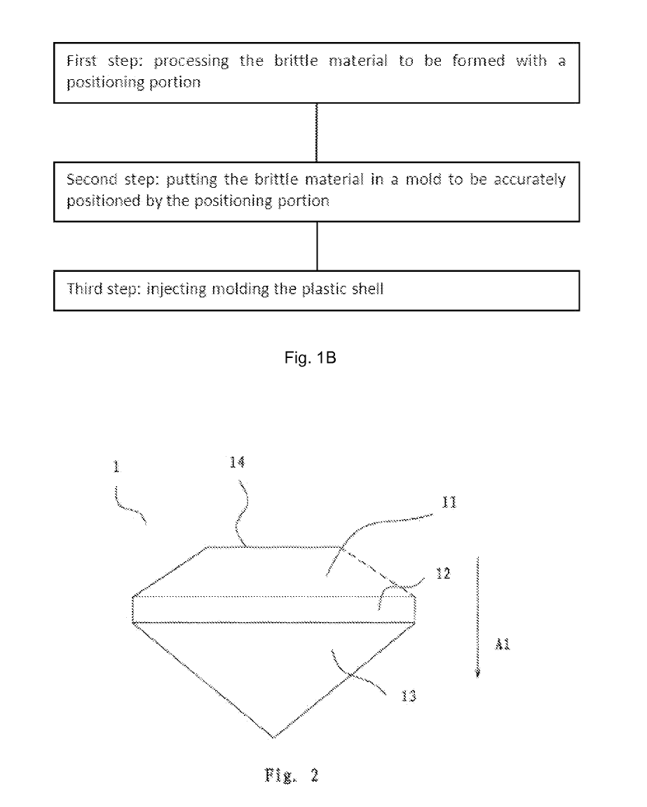

As shown in FIGS. 1 and 2, a method for inserting a precious stone 1 in a plastic shell of a mobile phone is provided. The method thereof comprises following steps:

The precious stone 1 is firstly processed (first step). And the processed stone 1 comprises an embedded portion 13 to be embedded into the plastic shell, an exposed portion 11 to be exposed from the shell, and a positioning portion 12 between the embedded portion 13 and the exposed portion 11 having a predetermined thickness in an embedding direction Al.

Then the positioning portion 12 and the exposed portion are put into a fixed mold core 31, and the precious stone 1 is positioned in the fixed mold core 31 by the positioning portion 12 (the second step).

A plastic material is injected into the mold 1 to form the plastic shell, in which the embedded portion 13 is embedded. At least the exposed portion 11 is exposed outside the plastic shell (the third step).

Each step mentioned above will be described in detail below with reference to the accompanying figures.

According to an embodiment of the method for inserting a precious stone in a plastic shell, the precious stone 1 has to be processed to accurately position the precious stone 1. As shown in FIG. 2, the embedded portion 13 of the processed precious stone 1 may be embedded into the plastic shell of a mobile phone. According to an embodiment of the invention, the embedded portion 13 may have a conical shape. However, the present invention is not limited thereto. To better position the precious stone, the embedded portion 13 may be formed with any other suitable shape, such as a truncated-cone, a pyramid shape, etc.

Further, the exposed portion 11 of the precious stone 1 may be formed with a plurality of planar surfaces to display the special optical effect of the precious stone, and additionally, to provide the user of the mobile phone with an aesthetic sense of pleasure. Alternatively, the embedded portion 13 may be formed with a plurality of planar surfaces to display the special optical effect of the precious stone. To better position the precious stone 1 during injection molding, an end face 14 on the exposed portion 11 of the precious stone 1 in parallel to a direction perpendicular to the embedding direction Al of the precious stone 1 may be processed to be planar, which will be described in detail hereinafter.

In an embodiment of the invention, the embedded portion 13 of the precious stone 1 has a conical shape, and the exposed portion 11 has a truncated cone shape.

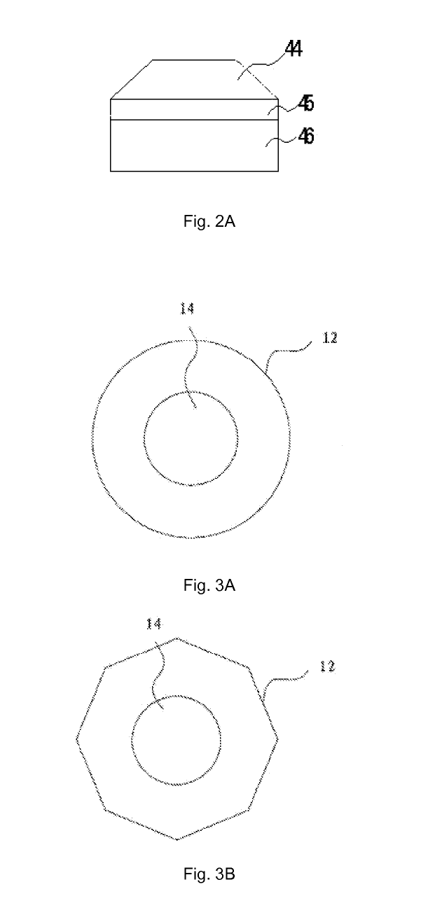

To accurately position the precious stone 1 in the mold 3, a position portion may be formed on the precious stone 1. In an embodiment of the invention, the positioning portion 12 is formed between the embedded portion 13 and the exposed portion 11, and the positioning portion 12 has a predetermined thickness in the embedding direction Al. As shown in FIGS. 3A and 3B, according to an embodiment of the invention, the positioning portion 12 formed between the embedded portion 13 and the exposed portion 11 includes a circular column or cylindrical portion in a direction in parallel to the embedding direction Al of the precious stone 1. According to another embodiment of the invention, the positioning portion 12 may have the configuration of a pyramid, which may have a polygon shape in a cross section of a prismatic body formed by prismatic surfaces in a direction perpendicular to the embedding direction Al of the precious stone 1, such as an octagon shown in FIG. 3B.

According to an embodiment of the invention, a height of the positioning portion 12 with the embedding direction Al falls in a range of about 1/10-⅕ of the height of the precious stone 1 in the embedding direction Al. Alternatively, the height of the positioning portion 12 may be about 1/10 of the height of the precious stone 1. For example, in an embodiment of the invention, the height of the positioning portion may be 0.5 mm. Because the height of the positioning portion 12 is rather small, it does not have a negative impact on the aesthetic appearance of the precious stone 1. Thus, with the positioning portion 12, the precious stone 1 can be positioned and/or fixed stably in the injection mold during injection molding.

Next, the above configured precious stone 1 is put into the fixed mold core 31 of the injection mold 3. That is, the exposed portion 11 and the positioning portion 12 of the precious stone 1 are put into the fixed mold core 31 of the mold 3. To be specific, the fixed mold core 31 of the mold 3 is formed with a cavity 33 for accommodating the embedded portion 13. The exposed portion 11 of the precious stone 1 may be accommodated in an aperture 32 formed on a bottom surface of the cavity 33, and the precious stone is positioned by, at least partially, engaging the positioning portion 12 with the aperture 32, as shown in FIG. 6. According to an embodiment of the invention, the aperture 32 has approximately the same dimension as that of the positioning portion 12, so that the positioning portion 12 may be accurately and stably engaged with the aperture 32. According to an embodiment of the invention, the positioning portion 12 may has a dimension slightly larger than that of the aperture 32, so that the positioning portion may further seal the aperture 32 to prevent the molten plastic from leaking. According to an embodiment of the invention, a plurality of apertures 32 may be formed on the fixed mold core 31 in a predetermined pattern or shape, such as a heart shape, star pentagon etc. to meet diversified aesthetic requirements of users to the appearance of the mobile phone. Therefore, more radiant effects of the shell may be achieved in combination with the glaring effects of the precious stone 1.

After the precious stone 1 is positioned in the mold 3, the molten plastic material is injected into the mold 3 to form the plastic shell (not shown) with the embedded portion 13 being embedded therein. The plastic material used in the insert injection molding may be selected with properties to facilitate the positioning of the precious stone in addition to performance during injection molding. In an embodiment of the invention, the plastic used during injection molding may be polycarbonate (PC) or polycarbonate Acrylonitrile Butadiene Styrene alloy (PC/ABS alloy) etc. However, the present invention is not limited thereto. From the description above, in a method of the present invention, the precious stone 1 is secured to the plastic shell, and it may seal the molten plastic and prevent the molten plastic from overflowing during injection molding, by means of the positioning portion 12, which may have a cylindrical configuration or a column, on the precious stone 1. Thus, burrs or flushes conventionally encountered are avoided. By inserting the precious stone 1 into the plastic shell of the mobile phone with injection molding, the negative effects of glue on the aesthetic appearance of the mobile phone and the falling off of the precious stone are reduced or eliminated.

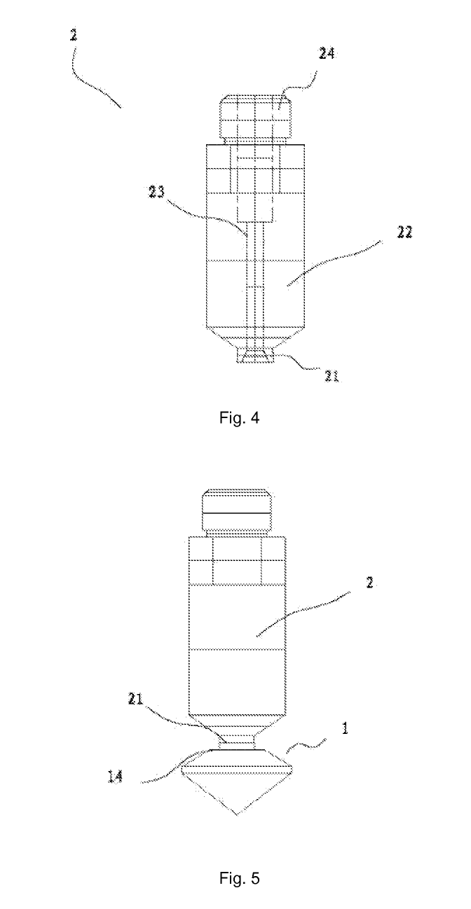

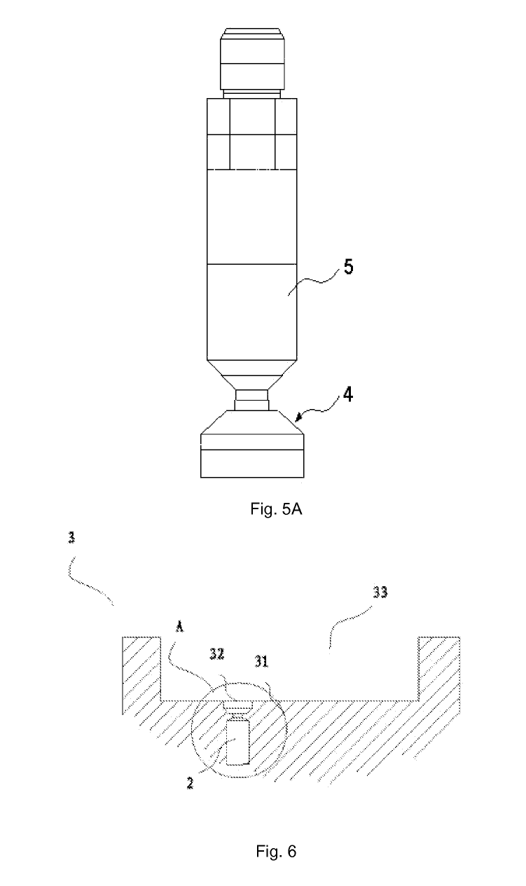

The method according to the invention will be further described with reference to FIGS. 4 and 5.

During injection molding, the station of the injection molding machine vibrates violently, and the precious stone 1 may still be dislocated even if at least a part of the positioning portion 12 is positioned in the aperture 32 in the mold 3 and the molten plastic is prevented from leaking. Further, the dimension of the precious stone 1 may not be precise enough. Thus, if the precious stone 1 does not fit well in the aperture 32 formed on an inner surface of the fixed mold core 31, the precious stone 1 may be dislocated easily. Therefore, the end face 14 on the exposed portion 11 of the precious stone 1 perpendicular to the embedding direction Al of the precious stone 1 may be processed to form a planar surface. In addition, a suction device 2 is installed in the fixed mold core 31 to mate with the end face 14, as shown in FIG. 4. The suction device 2 installed in the fixed mold core 31 suctions the end face 14 of the exposed portion 11 to further position the precious stone 1 during injection molding. Thus, the precious stone 1 may be better positioned during injection molding and is prevented from falling out of the plastic shell of the mobile phone. The suction device 2 comprises a main body 22, a suction nozzle 21 connected to a lower part of the main body 22, and a suctioning passage 23 through the main body 22 and the suction nozzle 21, as shown in FIG. 4. During use, the suction nozzle 21 tightly suctions the end face 14 of the precious stone 1. According to an embodiment of the invention, the elastic modulus, yielding strength or stretching strength of the main body 22 should be selected to endure the high temperature and high pressure during injection molding, such as 7.84 MPa, 1-7 MPa and 7-20 MPa respectively. According to an embodiment of the invention, the material of the suction device 2 may be silica gel. However, the present invention is not limited thereto; any other material that meets the conditions in the mold as mentioned above may be used in the injection molding.

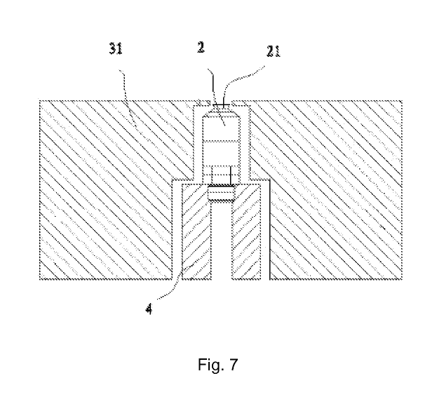

The size of the suction device should be considered in regard to that of the precious stone 1. As shown in FIG. 5, if the suction nozzle 21 of the suction device 2 has a larger cross section than the maximum cross section of the precious stone 1 in a direction perpendicular to the embedding direction Al, the precious stone 1 may be easily suctioned into the passage 23. Thus, according to an embodiment of the invention, the suction nozzle 21 should have a smaller cross section in a direction perpendicular to the embedding direction Al than that of the end face 14. Alternatively, the diameter of the cross section on the suction nozzle 21 contacting the end face 14 on the precious stone 1 is smaller than the diameter of the end face 14 to allow formation of sufficient negative pressure and prevent over-suction from happening. To facilitate installation and substitution of the manufacturing process, The suction device 2 can be attached to an insert 4 which may be inserted to the fixed mold core 31 by a connecting portion 24 formed on an end opposite to the suction nozzle 21, as shown in FIG. 7. The connecting portion 24 may be connected to the insert 4 by threads or a snap-on structure etc. Then, the insert 4 attached with the suction device 2 is installed into the fixed mold core 31. And when needed, the insert 4 may be extracted from the fixed mold core 31 and substituted with another suction device to be adapted to the molding of the plastic shell.

### EXAMPLE 2

As shown in FIGS. 1A and 2A, a method for inserting a glass 4 into a plastic shell of a mobile phone is provided. The method thereof comprises following steps:

The glass 4 is firstly processed (first step). And the processed glass 4 comprises an embedded portion 46 to be embedded into the plastic shell, an exposed portion 44 to be exposed from the shell, and a positioning portion 45 between the embedded portion 46 and the exposed portion 44 having a predetermined thickness in an embedding direction Al.

Then the positioning portion 45 and the exposed portion 44 are put into a fixed mold core 31, and the glass 4 is positioned in the fixed mold core 31 by the positioning portion 45 (the second step).

A plastic material is injected into the mold 1 to form the plastic shell, in which the embedded portion 46 is embedded. At least the exposed portion 44 is exposed outside the plastic shell (the third step).

Each step mentioned above will be described in detail below with reference to the accompanying figures.

According to an embodiment of the method for inserting a glass in a plastic shell, the glass 4 has to be processed to accurately position the glass 4. As shown in FIG. 2A, the embedded portion 46 of the processed glass 4 may be embedded into the plastic shell of a mobile phone. According to an embodiment of the invention, the embedded portion 46 may have a conical shape. However, the present invention is not limited thereto. To better position the glass, the embedded portion 46 may be formed with any other suitable shape, such as a truncated-cone, a pyramid shape etc.

Further, the exposed portion 44 of the glass 4 may be formed with a plurality of planar surfaces to display the special optical effect of the glass, and additionally, to provide the user of the mobile phone with an aesthetic sense of pleasure. Alternatively, the embedded portion 46 may be formed with a plurality of planar surfaces to display the special optical effect of the glass. To better position the glass 4 during injection molding, an end face 14 on the exposed portion 44 of the glass 4 in parallel to a direction perpendicular to the embedding direction Al of the glass 4 may be processed to be planar, which will be described in detail hereinafter.

In an embodiment of the invention, the embedded portion 46 of the glass 4 has a conical shape, and the exposed portion 44 has a truncated cone shape.

To accurately positioning the glass 4 in the mold 3, a position portion may be formed on the glass 4. In an embodiment of the invention, the positioning portion 45 is formed between the embedded portion 46 and the exposed portion 44, and the positioning portion 45 has a predetermined thickness in the embedding direction Al. As shown in FIGS. 3A and 3B, according to an embodiment of the invention, the positioning portion 45 formed between the embedded portion 46 and the exposed portion 44 includes a circular column or cylindrical portion in a direction in parallel to the embedding direction Al of the glass 4. According to another embodiment of the invention, the positioning portion 45 can be formed into a pyramid, which may have a polygon shape in a cross section of a prismatic body formed by prismatic surfaces in a direction perpendicular to the embedding direction Al of the glass 4, such as an octagon shown in FIG. 3B.

According to an embodiment of the invention, a height of the positioning portion 45 in the embedding direction Al falls in a range of about 1/10-⅕ of the height of the glass 4 in the embedding direction Al. Alternatively, the height of the positioning portion 45 may be about 1/10 of the height of the glass 4. For example, in an embodiment of the invention, the height of the positioning portion may be 0.5 mm. Because the height of the positioning portion 45 is rather small, it does not have a negative impact on the aesthetic appearance of the glass 4. Thus, with the positioning portion 45, the glass 4 can be positioned and/or fixed stably in the injection mold during injection molding.

Next, the above configured glass 4 is put into the fixed mold core 31 of the injection mold 3. That is, the exposed portion 44 and the positioning portion 45 of the glass 4 are put into the fixed mold core 31 of the mold 3. To be specific, the fixed mold core 31 of the mold 3 is formed with a cavity 33 for accommodating the embedded portion 13. The exposed portion 11 of the glass 4 may be accommodated in an aperture 32 formed on a bottom surface of the cavity 33, and the glass is positioned by, at least partially, engaging the positioning portion 45 in the aperture 32, as shown in FIG. 6. According to an embodiment of the invention, the aperture 32 has approximately the same dimension as that of the positioning portion 45, so that the positioning portion 45 may be accurately and stably engaged with the aperture 32. According to an embodiment of the invention, the positioning portion 45 may has a dimension slightly larger than that of the aperture 32, so that the positioning portion may further seal the aperture 32 to prevent the molten plastic from leaking. According to an embodiment of the invention, a plurality of apertures 32 may be formed on the fixed mold core 31 in a predetermined pattern or shape, such as a heart shape, star pentagon etc. to meet diversified aesthetic requirement of users to the appearance of the mobile phone. Therefore, more radiant effects of the shell may be achieved in combination with the glaring effects of the glass 4.

After the glass 4 is positioned in the mold 3, the molten plastic material is injected into the mold 3 to form the plastic shell (not shown) with the embedded portion 46 being embedded therein. The plastic material used in the insert injection molding may be selected with properties to facilitate the positioning of the glass in addition to performance during injection molding. In an embodiment of the invention, the plastic used during injection molding may be polycarbonate (PC) or polycarbonate Acrylonitrile Butadiene Styrene alloy (PC/ABS alloy) etc. However, the present invention is not limited thereto. From the description above, in the method of the present invention, the glass 4 is secured to the plastic shell, and it may seal the molten plastic and prevent the molten plastic from overflowing during injection molding, by means of the positioning portion 45, which may have a cylindrical configuration or a column portion, on the glass 1. Thus, burrs or flushes conventionally encountered are avoided. By inserting the glass 4 into the plastic shell of the mobile phone with injection molding, the negative effects of glue on the aesthetic appearance of the mobile phone and the falling off of the glass are reduced or eliminated.

The method according to the invention will be further described with reference to FIGS. 4 and 5A.

During injection molding, the station of the injection molding machine vibrates violently, and the glass 4 may still be dislocated even if at least a part of the positioning portion 45 is positioned in the aperture 32 in the mold 3 and preventing the molten plastic is prevented from leaking. Further, the dimension of the glass 4 may not be precise enough. Thus, if the glass 4 does not fit well with the aperture 32 formed on an inner surface of the fixed mold core 31, the glass 4 may be dislocated easily. Therefore, the end face 14 on the exposed portion 44 of the glass 4 perpendicular to the embedding direction Al of the glass 4 may be processed to form a planar surface.

In addition, a suction device 2 is installed in the fixed mold core 31 to mate with the end face 14, as shown in FIG. 4. The suction device 2 installed in the fixed mold core 31 suctions the end face 14 of the exposed portion 44 to further position the glass 4 during injection molding. Thus, the glass 4 may be better positioned during injection molding and is prevented from falling out of the plastic shell of the mobile phone. The suction device 2 comprises a main body 22, a suction nozzle 21 connected to a lower part of the main body 22, and a suctioning passage 23 through the main body 22 and the suction nozzle 21, as shown in FIG. 4. During use, the suction nozzle 21 tightly suctions the end face 14 of the glass 4. According to an embodiment of the invention, the elastic modulus, yielding strength or stretching strength of the main body 22 should be selected to endure the high temperature and high pressure during injection molding, such as 7.84 MPa, 1-7 MPa and 7-20 MPa respectively. According to an embodiment of the invention, the material of the suction device 2 may be silica gel. However, the present invention is not limited thereto; any other material that meets the conditions in the mold as mentioned above may be used in the injection molding.

The size of the suction device should be considered in regard to that of the glass 4. As shown in FIG. 5A, if the suction nozzle 21 of the suction device 2 has a larger cross section than the maximum cross section of the glass 4 in a direction perpendicular to the embedding direction Al, the glass 4 may be easily suctioned into the passage 23. Thus, according to an embodiment of the invention, the suction nozzle 21 should have a smaller cross section in a direction perpendicular to the embedding direction Al than that of the end face 14. Alternatively, the diameter of the cross section on the suction nozzle 21 contacting the end face 14 on the glass 4 is smaller than the diameter of the end face 14 to allow formation of sufficient negative pressure and prevent over-suction from happening. To facilitate installation and substitution of the manufacturing process, The suction device 2 can be attached to an insert 4 which may be inserted to the fixed mold core 31 by a connecting portion 24 formed on an end opposite to the suction nozzle 21, as shown in FIG. 7. The connecting portion 24 may be connected to the insert 4 by threads or a snap-on structure etc. Then, the insert 4 attached with the suction device 2 is installed into the fixed mold core 31. And when needed, the insert 4 may be extracted from the fixed mold core 31 and substituted with another suction device to be adapted to the molding of the plastic shell.

The foregoing description of the embodiments of the present invention has been provided for purpose of illustration and description. It is not intended to be exhaustive or limit the invention to the precise forms disclosed. Obviously, many modifications and variations will be apparent to practitioners skilled in the art. The embodiments are chosen and described in order to best explain the principles of the invention and its practical applications, thereby enabling those skilled in the art to understand the invention for various embodiments and with the various modifications as are suited to the particular use contemplated. It is intended that the scope of the invention shall be defined by the following claims and their equivalents.

What is claimed is:

1. A method of inserting a brittle material into a plastic shell, comprising:
a) processing the brittle material, so that the brittle material comprises an embedded portion to be embedded into the plastic shell, an exposed portion to be exposed outside the plastic shell, and a positioning portion between the embedded portion and the exposed portion;
b) putting the exposed portion and at least part of the positioning portion into a fixed mold core of an injection mold, with the brittle material being positioned in the fixed mold core by the positioning portion; and
c) injecting molten plastic into the mold to form the plastic shell, in which the embedded portion and at least part of the positioning portion are embedding with the exposed portion and the remaining of the positioning portion being exposed outside the plastic shell.

2. The method according to claim 1, wherein the positioning portion includes a circular column or a pyramid in an embedding direction of the brittle material.

3. The method according to claim 1, wherein the step a) further comprises:
processing an end face of the exposed portion of the brittle material into a planar surface perpendicular to the embedding direction of the brittle material.

4. The method according to claim 1, wherein the step b) further comprises:
suctioning the end face of the exposed portion with a suction device provided in the fixed mold core to position the brittle material during injection molding.

5. The method according to claim 4, wherein the suction device is attached to an insert which is in the fixed mold core.

6. The method according to claim 1, wherein the step a) further comprises:
processing the embedded portion of the brittle material into a conical shape;
and processing the exposed portion into a truncated-cone shape.

7. The method according to claim 1, wherein the positioning portion has a height of about 1/10 to ⅕ of that of the brittle material in the embedding direction.

8. The method according to claim 1, wherein an aperture is formed on the fixed mold core with a size substantially matching that of the positioning portion of the brittle material so that the brittle material can be accurately positioned in the aperture.

9. The method according to claim 8, wherein the fixed mold core includes a plurality of apertures which are arranged into a predetermined pattern.

10. An electronic device having a plastic shell made according to the method of claim 1.

11. A method of inserting a precious stone into a plastic shell, comprising:
a) processing the precious stone, so that the stone comprises an embedded portion to be embedded into the plastic shell, an exposed portion to be exposing outside the plastic shell, and a positioning portion between the embedded portion and the exposed portion;
b) putting the exposed portion and at least part of the positioning portion into a fixed mold core of an injection mold, with the precious stone being positioned in the fixed mold core by the positioning portion; and
c) injecting molten plastic into the mold to form the plastic shell, in which the embedded portion and at least part of the positioning portion are embedded into the plastic shell with the exposed portion and the remaining of the positioning portion being exposed outside the plastic shell.

12. The method according to claim 11, wherein the positioning portion includes a circular column or a pyramid in an embedding direction of the precious stone.

13. The method according to claim 11, wherein the step a) further comprises:
processing an end face of the exposed portion of the precious stone into a planar surface perpendicular to the embedding direction of the precious stone.

14. The method according to claim 11, wherein the step b) further comprises:
suctioning the end face of the exposed portion with a suction device provided in the fixed mold core to position the precious stone during injection molding.

15. The method according to claim 14, wherein the suction device is attached to an insert which is in the fixed mold core.

16. The method according to claim 11, wherein the step a) further comprises:
processing the embedded portion of the precious stone into a conical shape;
and processing the exposed portion into a truncated-cone shape.

17. The method according to claim 11, wherein the positioning portion has a height of about 1/10 to ⅕ of that of the precious stone in the embedding direction.

18. The method according to claim 11, wherein an aperture is formed on the fixed mold core with a size substantially matching that of the positioning portion of the precious stone so that the precious stone can be accurately positioned in the aperture.

19. The method according to claim 18, wherein the fixed mold core includes a plurality of apertures which are arranged into a predetermined pattern.

20. An electronic device having a plastic shell made according to the method of claim 11.
